(19) United States
(12) Patent Application Publication
(10) Pub. No.: US 2018/0267587 A1
(43) Pub. Date: Sep. 20, 2018

(54) COMPARING ELECTRICAL QUANTITY OUTPUT BY POWER ADAPTER TO ELECTRICAL QUANTITY INPUT BY COMPUTING DEVICE

(71) Applicant: GOOGLE INC., Mountain View, CA (US)

(72) Inventors: Scott ALDOUS, Palo Alto, CA (US); Anta TRIMUA, Fremont, CA (US); Nima LOTFIZADEH, Mountain View, CA (US); Joseph LATOURETTE, San Jose, CA (US)

(21) Appl. No.: 15/463,479

(22) Filed: Mar. 20, 2017

(51) Int. Cl. G06F 1/28; G01R 31/40; G06F 1/30

(52) U.S. Cl. CPC G06F 1/28; G06F 1/30; G01R 31/40

(57) ABSTRACT

A power adapter may include a power output module configured to supply electric current to a computing device, an electrical monitor configured to measure an output electrical quantity of the power output module, a communication port configured to receive, from the computing device, an indication of an input electrical quantity, a comparator configured to determine a difference between the measured output electrical quantity and the indicated input electrical quantity, and a controller configured to instruct the power output module to stop supplying the electric current to the computing device based on the difference satisfying a warning state.

### TECHNICAL FIELD

This description relates to providing power to computing devices.

### BACKGROUND

Power adapters may provide power to computing devices by supplying current to the computing devices. At times, a short may occur within the power adapter, the computing device, or an interconnecting cable between them if present, causing current to leak. The short may cause damage to the power adapter, the interconnecting cable, and/or to the computing devices.

### SUMMARY

According to an example, a power adapter may include a power output module configured to supply electric current to a computing device, an electrical monitor configured to measure an output electrical quantity of the power output module, a communication port configured to receive, from the computing device, an indication of an input electrical quantity, a comparator configured to determine a difference between the measured output electrical quantity and the indicated input electrical quantity, and a controller configured to instruct the power output module to stop supplying the electric current to the computing device based on the difference satisfying a warning state.

According to an example, a power adapter may include a power output module configured to supply electric current to a computing device, an electrical monitor configured to measure an output electrical quantity of the power output module, a communication port configured to send, to the computing device, an indication of the measured output electrical quantity, and receive, from the computing device, an instruction to stop supplying the electric current, and a controller configured to, in response to the communication port receiving the instruction to stop supplying the electric current, instruct the power output module to stop supplying the electric current to the computing device.

According to an example, a computing device may include a display, a rechargeable battery configured to provide power to the display, a power input module configured to absorb electric current from a power adapter and supply electric current to the rechargeable battery, an electrical monitor configured to measure an input electrical quantity of the power input module, a communication port configured to receive, from the power adapter, an indication of an output electrical quantity, a comparator configured to determine a difference between the measured input electrical quantity and the indicated output electrical quantity, and a controller configured to instruct the power adapter to stop supplying the electric current to the computing device based on the difference satisfying a warning state.

According to an example, a computing device may include a display, a rechargeable battery configured to provide power to the display, a power input module configured to absorb electric current from a power adapter and supply electric current to the rechargeable battery, an electrical monitor configured to measure an input electrical quantity of the power input module, and a communication port configured to send, to the power adapter, an indication of the measured input electrical quantity.

According to an example, a power adapter may include means for supplying electric current to a computing device, means for measuring an output electrical quantity of the power output module, means for receiving, from the computing device, an indication of an input electrical quantity, means for determining a difference between the measured output electrical quantity and the indicated input electrical quantity, and means for instructing the means for supplying electric current to stop supplying the electric current to the computing device based on the difference satisfying a warning state.

According to an example, a power adapter may include means for supplying electric current to a computing device, means for measuring an output electrical quantity of the power output module, means for sending, to the computing device, an indication of the measured output electrical quantity, means for receiving, from the computing device, an instruction to stop supplying the electric current, and means for, in response to the means for receiving the instruction receiving the instruction to stop supplying the electric current, instructing the means for supplying electric current to stop supplying the electric current to the computing device.

According to an example, a computing device may means for displaying information, means for providing power to the means for displaying information, means for absorbing electric current from a power adapter and supplying electric current to the means for providing power, means for measuring an input electrical quantity of the means for absorbing electric current, means for receiving receive, from the power adapter, an indication of an output electrical quantity, means for determining a difference between the measured input electrical quantity and the indicated output electrical quantity, means for instructing the power adapter to stop supplying the electric current to the computing device based on the difference satisfying a warning state.

According to an example, a computing device may include means for displaying information, means for providing power to the means for displaying information, means for absorbing electric current from a power adapter and supply electric current to the means for providing power, means for measuring an input electrical quantity of the power input module, and means for sending, to the power adapter, an indication of the measured input electrical quantity.

The details of one or more implementations are set forth in the accompanying drawings and the description below. Other features will be apparent from the description and drawings, and from the claims.

### BRIEF DESCRIPTION OF THE DRAWINGS

FIG. 1A is a perspective view showing a power adapter supplying current to a computing device according to an example implementation.

FIG. 1B shows connections between the power adapter and the computing device according to an example implementation.

FIG. 2 is a block diagram of the power adapter according to an example implementation.

FIG. 3 is a block diagram of the computing device according to an example implementation.

FIG. 4 is a timing diagram showing functions performed by, and messages exchanged between, the power adapter and the computing device according to an example implementation in which the power adapter compares the measured electrical quantities.

FIG. 5 is a timing diagram showing functions performed by, and messages exchanged between, the power adapter and the computing device according to an example implementation in which the computing device compares the measured electrical quantities.

FIG. 6 shows an example of a computer device and a mobile computer device that can be used to implement the techniques described here.

### DETAILED DESCRIPTION

Power adapters may supply current to computing devices, such as by rectifying an alternating current (AC) voltage source into a direct current (DC) voltage source and supplying current to the computing device via a positive line or wire and a ground or negative line or wire. Ideally, the positive line or wire will be insulated from the ground or negative line or wire, and the resistance between the positive line or wire and the ground or negative line or wire will be infinite. In this circumstance, the current absorbed by the computing device will be equal to the current supplied by the power adapter, the voltage difference between the positive line or wire and the ground or negative line or wire at the computing device will be equal to or almost equal to the voltage difference between the positive line or wire and the ground or negative line or wire at the power adapter (a small difference in voltage may be caused by a voltage drop across the lines or wires), and/or the power supplied by the power adapter will be equal to or almost equal to the power absorbed by the computing device (a small difference in power may be caused by the voltage drop across the lines or wires).

At times, a defect may cause current to flow from the positive line or wire to the ground line or wire. The current flow may cause overheating or other damage to the power adapter, the computing device, and/or an interconnecting cable between them if present.

To detect a defect causing current to flow from the positive line or wire to the ground line or wire, the power adapter and the computing device may each perform measurements on an electrical quantity, such as electrical current, voltage, or power, at their respective node. Either or both of the power adapter and computing device may send the measured electrical quantity to the other of the power adapter and computing device. Either or both of the power adapter and the computing device may compare the measured electrical quantities. If the difference between the measured electrical quantities meets or exceeds a threshold (such as five percent (5%) of an expected electrical quantity or ten percent (10%) of the expected electrical quantity), then a fault or error condition may be considered to occur. In such a fault or error condition, which may be considered a warning state, the power adapter may stop supplying current to the computing device, the computing device may present a warning statement, and/or the computing device may shut down.

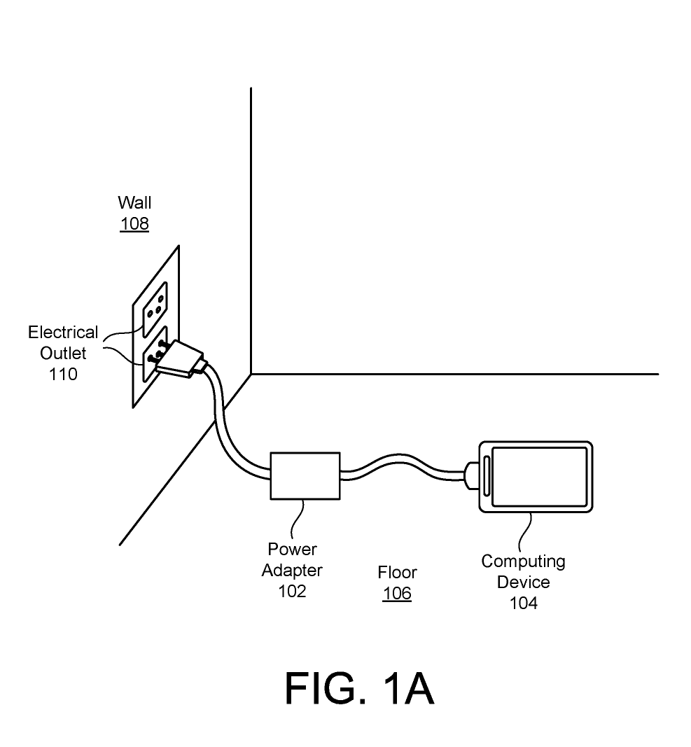

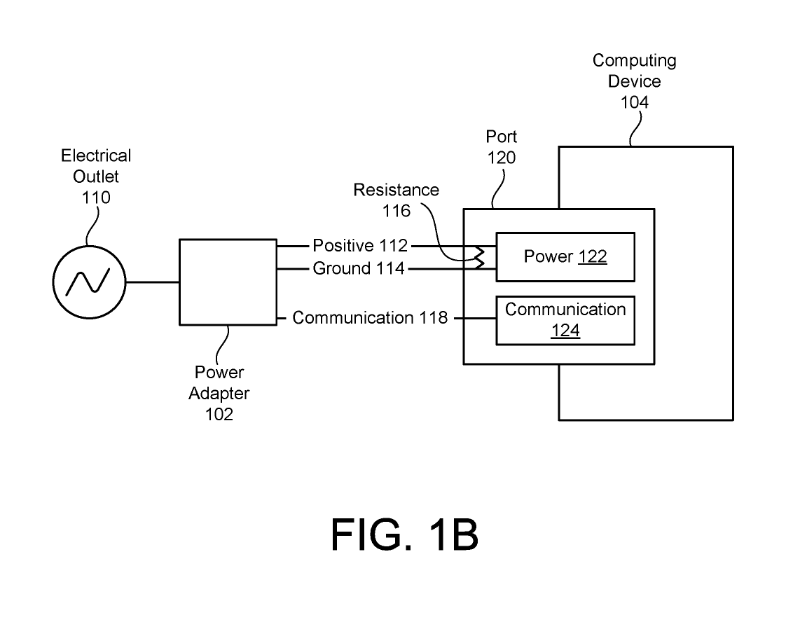

FIG. 1A is a perspective view showing a power adapter 102 supplying current to a computing device 104 according to an example implementation. The power adapter 102 may absorb power from an electrical outlet 110. The electrical outlet 110 may be surrounded by a wall 108 that is adjacent to a floor 106 of a building. The electrical outlet 110 may supply an alternating current (AC) voltage to the power adapter 102, and the power adapter 102 may rectify the AC voltage into a direct current (DC) voltage to supply current to the computing device 104. The power adapter 102 and/or computing device 104 may rest on the floor 106, on a table, supported by the AC blades in the case of a direct plug-in AC adapter, or be held by a user. The computing device 104 may include a portable computing device such as a smartphone, tablet computer, or laptop or notebook computer, as non-limiting examples.

FIG. 1B shows connections between the power adapter 102 and the computing device 104 according to an example implementation. As discussed above, the electrical outlet 110 may supply an AC voltage to the power adapter 102. The power adapter 102 may rectify the AC voltage into a DC voltage.

The power adapter 102 may provide power to the computing device 104 and may communicate with the computing device 104 by sending and receiving electrical signals to the computing device 104. The power adapter 102 may provide the power to the computing device 104 and communicate with the computing device 104 via a wired and/or guided connection, such as via electrical lines or wires. The power adapter 102 may provide the power to the computing device 104 and communicate with the computing device 104 according to a Universal Serial Bus (USB) protocol, such as USB Type-C (USB-C), which may include a twenty-four pin fully reversible plug connector system allowing transport of data and energy. The power adapter 102 may include, for example, a USB power supply, such as a USB-C power supply.

The power adapter 102 may provide power to the computing device 104 and communicate with the computing device 104 via a port 120. The port 120 may be a USB port, such as a USB-C port. The port 120 may include a power input module 122 that absorbs current and/or power supplied by the power adapter 102, and a communication port 124 that sends and receives electrical signals to and from the power adapter 102.

The power adapter 102 may supply current or power to the power input module 122 of the computing device 104 via one or more positive lines or wires 112 and one or more ground or negative lines or wires 114. The one or more positive lines or wires 112 and one or more ground or negative lines or wires 114 may be included in a cable of the power adapter 102 and may plug into the port 120 of the computing device 104. In a properly functioning computing device 104, the one or more positive lines or wires 112 may be insulated from the one or more ground or negative lines or wires 114 within the computing device 104, and an effective resistance 116 between one or more positive lines or wires 112 and the one or more ground or negative lines or wires 114 may be infinite. However, at times a defect within the port 120 may cause the resistance 116 to be less than infinite, and a small leakage current may flow within the port 120 from the one or more positive lines or wires 112 to the one or more ground or negative lines or wires 114.

The power adapter 102 and computing device 104 may each measure an electrical quantity, such as current supplied or absorbed, power supplied or absorbed, or voltage difference, at the respective device. Either or both of the power adapter 102 and computing device 104 may send the measured electrical quantity to the other of the power adapter and computing device 104. Either or both of the power adapter 102 and computing device 104 may compare the two measured electrical quantities. If the comparison results in a difference that meets or exceeds a threshold, the difference may indicate a leakage current flowing from the one or more positive lines or wires 112 to the one or more ground or negative wires 114 due to a defect in the computing device 104 or in the mating connector that is mated to the computing device 104. The power adapter 102 and/or computing device 104 may perform one or more actions based on a warning state indicating the leakage current, such as the power adapter 102 stopping supplying current to the computing device 104, the computing device 104 presenting an error statement to a user of the computing device 104, and/or the computing device 104 shutting down.

The cable of the power adapter 102 may include one or more communication lines or wires 118 that plug into a communication port 124 of the port 120 of the computing device 104. The power adapter 102 and computing device 104 may send and receive electrical signals to and from each other via the one or more communication lines or wires 118.

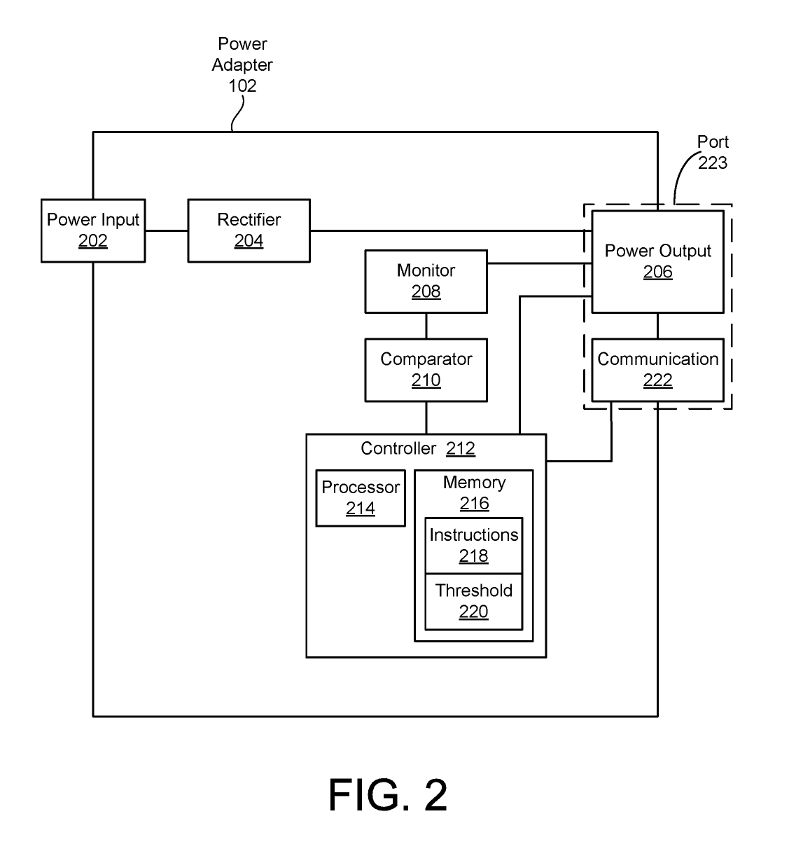

FIG. 2 is a block diagram of the power adapter 102 according to an example implementation. The power adapter 102 may include a power input module 202. The power input module 202 may receive electric power and/or current from an external source, such as the electrical outlet 110 shown and described with respect to FIGS. 1A and 1B. The power adapter 102 may include a rectifier circuit 204. In the example in which the power input module 202 absorbs power and/or current from an AC voltage source such as an electrical outlet 110, the rectifier circuit 204 may rectify and/or convert the AC voltage to DC voltage for supply to the computing device 104 (not shown in FIG. 2).

The power adapter 102 may include a power output module 206. The power output module 206 may supply electric current and/or power to the computing device 104, such as via the one or more positive lines or wires 112 and the one or more ground or negative lines or wires 114. The power adapter 102 may also include a communication port 222. The communication port 222 may send and receive electrical signals to and from the computing device 104. The electrical signals may include measured electrical quantities, such as current, power, and/or voltage, and/or warning messages of a warning state indicating that a difference between the measured electrical quantities meets or exceeds a threshold. The electrical signals from communication port 222 may be transmitted to the computing device 104 together with the power provided by power output module 206 through a single combined output port 223.

The power adapter 102 may include an electrical monitor 208. The electrical monitor 208 may measure an output electrical quantity supplied and/or provided by the power output module 206 to the computing device 104. The output electrical quantity may include, for example, an output current supplied by the power output module 206 to the computing device 104, an output power supplied by the power output module 206 to the computing device 104, and/or an output voltage and/or output voltage difference provided by the power output module 206 to the computing device 104.

The power adapter 102 may include a comparator 210. The comparator 210 may compare the measured output electrical quantity to an input electrical quantity received from, and measured by, the computing device 104. The comparison may determine a difference between the output electrical quantity and the input electrical quantity.

The power adapter 102 may include a controller 212. The controller 212 may control functions of modules and/or components of the power adapter 102, such as by instructing the modules and/or components of the power adapter 102 to perform and/or cease performing actions described with respect to the modules and/or components of the power adapter 102 herein. The controller 212 may, for example, instruct the power output module 206 to stop supplying electric current to the computing device 104 based on the warning state indicating that the difference determined by the comparator 210 meets or exceeds a threshold.

The controller 212 may include at least one processor 214. The at least one processor 214 may execute instructions, such as instructions 218 stored in memory 216, to cause the power adapter 102 to perform any combination of functions, methods, and/or techniques described herein with respect to the power adapter 102.

The controller 212 may include at least one memory device 216. The at least one memory device 216 may include a non-transitory computer-readable storage medium. The at least one memory device 216 may store instructions 218 that, when executed by the at least one processor 214, cause the power adapter 102 to perform any combination of functions, methods, and/or techniques described herein with respect to the power adapter 102.

The memory 216 may store a threshold 220. The threshold 220 may be a difference in measured electrical quantities, such as a current difference, power difference, and/or voltage difference. The threshold 220 may be a minimum difference at which, and/or beyond which, the controller 212 indicates a warning state that causes the power adapter 102 to perform or stop performing actions, such as stopping supplying current to the computing device 104 based on the difference meeting or exceeding the threshold 220. The controller 212 may update and/or change the threshold 220 based on instructions and/or firmware updates received from entities outside the power adapter 102, such as firmware updates received from a manufacturer of the power adapter 102 received via the computing device 104.

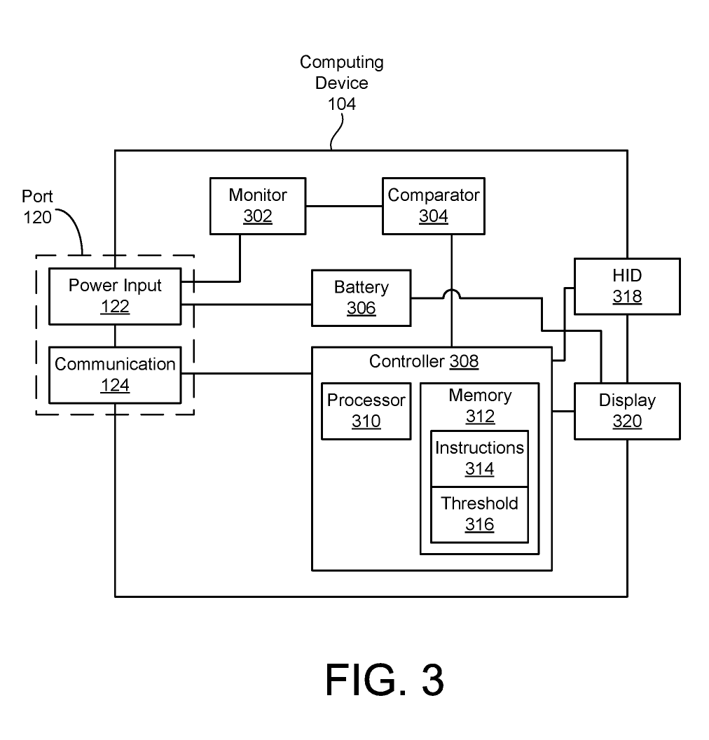

FIG. 3 is a block diagram of the computing device 104 according to an example implementation. The computing device 104 may include the port 120 for absorbing power and/or current from the power adapter 102 and sending and receiving signals to and from the power adapter 102. The port 120 may include a USB port, such as a USB-C port. The port 120 may include a power input module 122 that absorbs electric current from the power adapter 102 and supplies electric current to a battery 306 of the computing device 104. The port 120 may also include a communication port 124 that sends and receives signals to and from the power adapter 102. The signals may include indications of measured electrical quantities, error messages, and/or instructions to stop supplying electric current.

The computing device 104 may include a battery 306. The battery 306 may provide power to components and/or modules of the computing device 104, such as a display 320 of the computing device 104. The battery 306 may be a rechargeable battery, such as a lithium-ion (Li-ion) battery. In the example in which the battery 306 is a rechargeable battery, the battery 306 may be recharged by current supplied by the power input module 122.

The computing device 104 may include an electrical monitor 302. The electrical monitor 302 may measure an input electrical quantity, such as input current, input power, or input voltage, at the power input 122.

The computing device 104 may include a comparator 304. The comparator 304 may compare the input electrical quantity measured by the monitor 302 to the output electrical quantity measured by the power adapter 102 and received by the communication port 124 to determine a difference between the output electrical quantity and the input electrical quantity. The comparator 304 may provide the difference to a controller 308.

The computing device 104 may include the controller 308. The controller 308 may control operations of components or modules within the computing device 104. The controller 308 may receive input from components or modules of the computing device 104, such as the communication port 124, the comparator 304, and a human interface device (HID) 318, and may provide output to components or modules of the computing device 104, such as the communication port 124, the comparator 304, and a display 320.

The controller 308 may include at least one processor 310. The at least one processor 310 may execute instructions to cause the computing device 104 to perform any combination of functions, methods, and/or techniques described herein with respect to the computing device 104.

The controller 308 may include at least one memory device 312. The at least one memory device 312 may include a non-transitory computer-readable storage medium. The at least one memory device 312 may include instructions 314. The instructions 314, when executed by the at least one processor 310, may cause the computing device 104 to perform any combination of the methods, functions, or techniques described herein with respect to the computing device 104.

The at least one memory device 312 may store a threshold 316. The threshold 316 may be a difference in measured electrical quantities, such as a current difference, power difference, and/or voltage difference. The threshold 316 may be a minimum difference at which, and/or beyond which, the controller 308 indicates a warning state that causes the computing device 104 to perform or stop performing actions, such as sending an instruction to the power adapter 102 to stop supplying current to the computing device 104, presenting a warning statement on the display 320, and/or shutting down. The controller 308 may update and/or change the threshold 316 based on instructions and/or operating system updates received from entities outside the computing device 104, such as operating system updates received from a manufacturer of the computing device 104 and/or a manufacturer of an operating system running on the computing device 104.

The computing device 104 may include the human interface device (HID) 318. The HID 318 may include components for receiving input from a human user, such as buttons, a keyboard, a mouse or trackpad, and/or a touchscreen, as non-limiting examples. The HID 318 may provide the input to the controller 308.

The computing device 104 may include the display 320. The display 320 may present graphical and/or visual output based on input received by the display 320 from the controller 308. The display 320 may, for example, present a warning statement indicating a defect in the computing device 104 based on the difference between the output electrical quantity and the input electrical quantity, determined by either the comparator 304 or the comparator 210, exceeding either threshold 220, 316.

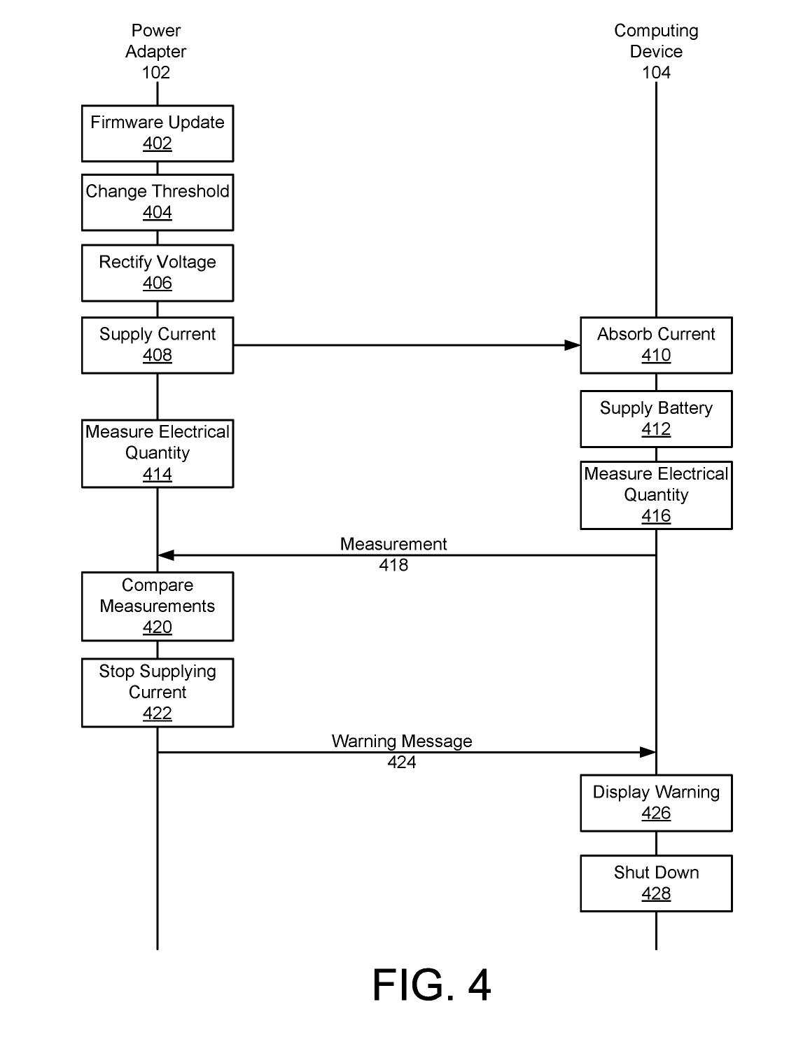

FIG. 4 is a timing diagram showing functions performed by, and messages exchanged between, the power adapter 102 and the computing device 104 according to an example implementation in which the power adapter 102 compares the measured electrical quantities. The power adapter 102 may receive and implement a firmware update (402). The firmware update may fix bugs in code for the power adapter's 102 firmware, and/or change parameters, such as the threshold 220. In response to receiving the firmware update (402), the power adapter 102 may change and/or modify the threshold 220 (406). The change and/or modification may increase or decrease the threshold 220 based on analysis by the manufacturer of the power adapter 102 of what value for the threshold will most accurately detect defects related to supplying power to the computing device 104.

The power adapter 102 may absorb current and/or receive power, such as from the electrical outlet 110, and may rectify the voltage into a DC voltage (406). The power adapter 102 may supply current (408) to the computing device 104. The computing device 104 may absorb the current (410) supplied by the power adapter 102. Upon absorbing the current (410), the computing device 104 may supply current and/or power to the battery 306 (412), recharging the battery 306.

The electrical monitor 208 of the power adapter 102 may measure the electrical quantity (414) supplied by the power output module 206 to the computing device. The electrical monitor 302 of the computing device 104 may also measure the electrical quantity (416) absorbed by the power input module 122 from the power adapter 102. In this example in which the power adapter 102 compares the measured electrical quantities, the computing device 104 may send the measurement 418 of the input electrical quantity to the power adapter 102. The measurement 418 may indicate the input electrical quantity.

The comparator 210 of the power adapter 102 may compare the measured output electrical quantity to the measured and/or indicated input electrical quantity (420) to determine a difference between the output electrical quantity and the input electrical quantity. The controller 212 of the power adapter 102 may determine whether the difference meets or exceeds the threshold 220 stored by the power adapter 102. In an example, if the difference does meet the threshold 220, then the difference may be considered to satisfy a warning state. In another example, if the difference exceeds the threshold 220, then the difference may be considered to satisfy the warning state. The warning state may be considered to be satisfied if the difference meets the threshold 220, if the difference exceeds the threshold 220, or if the difference meets or exceeds the threshold 220. If the difference satisfies the warning state, then the power adapter 102 may stop supplying current (422) to the computing device 104 based on the difference satisfying the warning state, and may send a warning message 424 to the computing device 104. The computing device 104 may respond to receiving the warning message 424 by displaying a warning (426) on the display 320 indicating that some component of the computing device 104 is defective, and/or by shutting down (428).

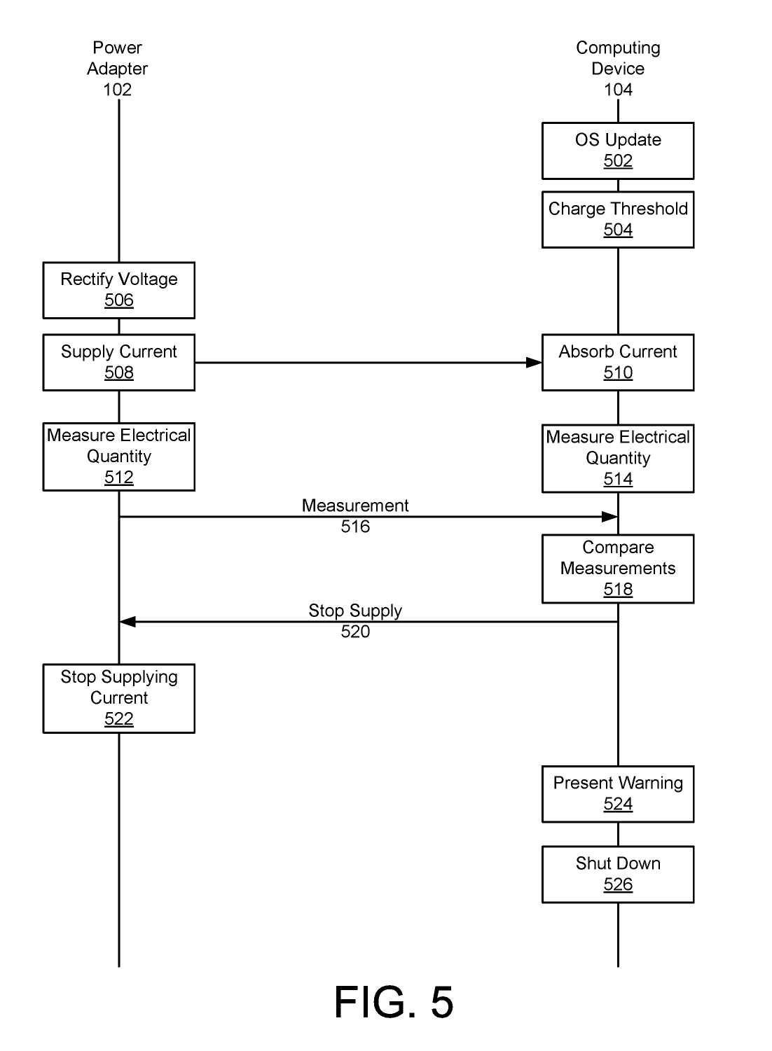

FIG. 5 is a timing diagram showing functions performed by, and messages exchanged between, the power adapter 102 and the computing device 104 according to an example implementation in which the computing device 104 compares the measured electrical quantities. The computing device 104 may receive an operating system (OS) update (502). The computing system 104 may receive the operating system update (502) from a manufacturer of the computing device 104 and/or operating system. The operating system update may include bug fixes, security improvements, and/or changes to parameters, such as the threshold 316. The computing device 104 may change the threshold 316 (504), either increasing or decreasing the threshold 316, based on analysis by the manufacturer of the computing device 104 and/or operating system of an optimal threshold for determining defects in the computing device 104.

The power adapter 102 may absorb current and/or power, such as from the electrical outlet 110, and may rectify an AC voltage to a DC voltage (506) as described above. The power adapter 102 may supply current (508) to the computing device 104, and the computing device 104 may absorb the current (510) supplied by the power adapter 102, as described above. The computing device 104 may charge the battery 306 using the absorbed current. The power adapter 102 may measure the output electrical quantity (512), and the computing device 104 may measure the input electrical quantity (514), as described above.

In this example in which the computing device 104 compares the measured electrical quantities, the power adapter 102 may send the measurement 516 of the output electrical quantity to the computing device 104. The measurement 516 may indicate the output electrical quantity. The comparator 304 may compare the measured and/or indicated output electrical quantity received from the power adapter 102 to the input electrical quantity measured by the electrical monitor 302 (518) to determine a difference between the measured output electrical quantity and the measured input electrical quantity. The comparator 304 may provide the difference to the controller 308, and the controller 308 may determine whether the difference satisfies a warning state. In an example, the difference may satisfy the warning state if the difference meets the threshold 316. In another example, the difference may satisfy the warning state if the difference meets or exceeds the threshold 316. The warning state may be considered to be satisfied if the difference meets the threshold 316, if the difference exceeds the threshold 316, or if the difference meets or exceeds the threshold 316.

If the controller 308 determines that the warning state is satisfied, then the controller 308 and/or computing device 104 may send a stop supply instruction 520 to the power adapter 102. The power adapter 102 may respond to receiving the stop supply instruction 520 by stopping supplying current (522) to the computing device 104. The computing device 104 may also, based on the controller 308 determining that the warning state is satisfied, present a warning statement (524) on the display 320 indicating a defect in the computing device 104, and/or shut down (526), preventing damage to the computing device 104.

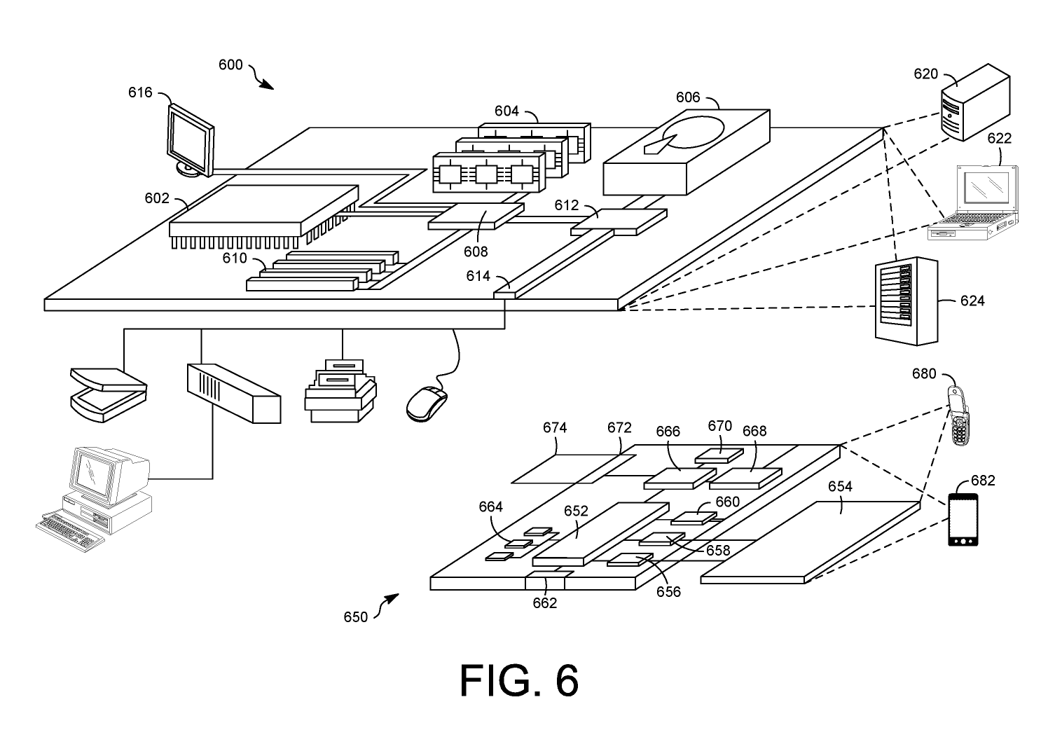

FIG. 6 shows an example of a generic computer device 600 (which may be an example of the computing device 104) and a generic mobile computer device 650 (which may be another example of the computing device 104), which may be used with the techniques described here. Computing device 600 is intended to represent various forms of digital computers, such as laptops, desktops, tablets, workstations, personal digital assistants, televisions, servers, blade servers, mainframes, and other appropriate computing devices. Computing device 650 is intended to represent various forms of mobile devices, such as personal digital assistants, cellular telephones, smart phones, and other similar computing devices. The components shown here, their connections and relationships, and their functions, are meant to be exemplary only, and are not meant to limit implementations of the inventions described and/or claimed in this document.

Computing device 600 includes a processor 602, memory 604, a storage device 606, a high-speed interface 608 connecting to memory 604 and high-speed expansion ports 610, and a low speed interface 612 connecting to low speed bus 614 and storage device 606. The processor 602 can be a semiconductor-based processor. The memory 604 can be a semiconductor-based memory. Each of the components 602, 604, 606, 608, 610, and 612, are interconnected using various busses, and may be mounted on a common motherboard or in other manners as appropriate. The processor 602 can process instructions for execution within the computing device 600, including instructions stored in the memory 604 or on the storage device 606 to display graphical information for a GUI on an external input/output device, such as display 616 coupled to high speed interface 608. In other implementations, multiple processors and/or multiple buses may be used, as appropriate, along with multiple memories and types of memory. Also, multiple computing devices 600 may be connected, with each device providing portions of the necessary operations (e.g., as a server bank, a group of blade servers, or a multi-processor system).

The memory 604 stores information within the computing device 600. In one implementation, the memory 604 is a volatile memory unit or units. In another implementation, the memory 604 is a non-volatile memory unit or units. The memory 604 may also be another form of computer-readable medium, such as a magnetic or optical disk.

The storage device 606 is capable of providing mass storage for the computing device 600. In one implementation, the storage device 606 may be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described above. The information carrier is a computer- or machine-readable medium, such as the memory 604, the storage device 606, or memory on processor 602.

The high speed controller 608 manages bandwidth-intensive operations for the computing device 600, while the low speed controller 612 manages lower bandwidth-intensive operations. Such allocation of functions is exemplary only. In one implementation, the high-speed controller 608 is coupled to memory 604, display 616 (e.g., through a graphics processor or accelerator), and to high-speed expansion ports 610, which may accept various expansion cards (not shown). In the implementation, low-speed controller 612 is coupled to storage device 606 and low-speed expansion port 614. The low-speed expansion port, which may include various communication ports (e.g., USB, Bluetooth, Ethernet, wireless Ethernet) may be coupled to one or more input/output devices, such as a keyboard, a pointing device, a scanner, or a networking device such as a switch or router, e.g., through a network adapter.

The computing device 600 may be implemented in a number of different forms, as shown in the figure. For example, it may be implemented as a standard server 620, or multiple times in a group of such servers. It may also be implemented as part of a rack server system 624. In addition, it may be implemented in a personal computer such as a laptop computer 622. Alternatively, components from computing device 600 may be combined with other components in a mobile device (not shown), such as device 650. Each of such devices may contain one or more of computing device 600, 650, and an entire system may be made up of multiple computing devices 600, 650 communicating with each other.

Computing device 650 includes a processor 652, memory 664, an input/output device such as a display 654, a communication interface 666, and a transceiver 668, among other components. The device 650 may also be provided with a storage device, such as a microdrive or other device, to provide additional storage. Each of the components 650, 652, 664, 654, 666, and 668, are interconnected using various buses, and several of the components may be mounted on a common motherboard or in other manners as appropriate.

The processor 652 can execute instructions within the computing device 650, including instructions stored in the memory 664. The processor may be implemented as a chipset of chips that include separate and multiple analog and digital processors. The processor may provide, for example, for coordination of the other components of the device 650, such as control of user interfaces, applications run by device 650, and wireless communication by device 650.

Processor 652 may communicate with a user through control interface 658 and display interface 656 coupled to a display 654. The display 654 may be, for example, a TFT LCD (Thin-Film-Transistor Liquid Crystal Display) or an OLED (Organic Light Emitting Diode) display, or other appropriate display technology. The display interface 656 may comprise appropriate circuitry for driving the display 654 to present graphical and other information to a user. The control interface 658 may receive commands from a user and convert them for submission to the processor 652. In addition, an external interface 662 may be provided in communication with processor 652, so as to enable near area communication of device 650 with other devices. External interface 662 may provide, for example, for wired communication in some implementations, or for wireless communication in other implementations, and multiple interfaces may also be used.

The memory 664 stores information within the computing device 650. The memory 664 can be implemented as one or more of a computer-readable medium or media, a volatile memory unit or units, or a non-volatile memory unit or units. Expansion memory 674 may also be provided and connected to device 650 through expansion interface 672, which may include, for example, a SIMM (Single In Line Memory Module) card interface. Such expansion memory 674 may provide extra storage space for device 650, or may also store applications or other information for device 650. Specifically, expansion memory 674 may include instructions to carry out or supplement the processes described above, and may include secure information also. Thus, for example, expansion memory 674 may be provided as a security module for device 650, and may be programmed with instructions that permit secure use of device 650. In addition, secure applications may be provided via the SIMM cards, along with additional information, such as placing identifying information on the SIMM card in a non-hackable manner.

The memory may include, for example, flash memory and/or NVRAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 664, expansion memory 674, or memory on processor 652, that may be received, for example, over transceiver 668 or external interface 662.

Device 650 may communicate wirelessly through communication interface 666, which may include digital signal processing circuitry where necessary. Communication interface 666 may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver 668. In addition, short-range communication may occur, such as using a Bluetooth, WiFi, or other such transceiver (not shown). In addition, GPS (Global Positioning System) receiver module 670 may provide additional navigation- and location-related wireless data to device 650, which may be used as appropriate by applications running on device 650.

Device 650 may also communicate audibly using audio codec 660, which may receive spoken information from a user and convert it to usable digital information. Audio codec 660 may likewise generate audible sound for a user, such as through a speaker, e.g., in a handset of device 650. Such sound may include sound from voice telephone calls, may include recorded sound (e.g., voice messages, music files, etc.) and may also include sound generated by applications operating on device 650.

The computing device 650 may be implemented in a number of different forms, as shown in the figure. For example, it may be implemented as a cellular telephone 680. It may also be implemented as part of a smart phone 682, personal digital assistant, or other similar mobile device.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here can be implemented on a computer having a display device (e.g., a CRT (cathode ray tube) or LCD (liquid crystal display) monitor) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing system that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (“LAN”), a wide area network (“WAN”), and the Internet.

The computing system can include clients and servers. A client and server are generally remote from each other and typically interact through a communication network. The relationship of client and server arises by virtue of computer programs running on the respective computers and having a client-server relationship to each other.

A number of embodiments have been described. Nevertheless, it will be understood that various modifications may be made without departing from the spirit and scope of the invention.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

What is claimed is:

1. A power adapter comprising:
a power output module configured to supply electric current to a computing device;
an electrical monitor configured to measure an output electrical quantity of the power output module;
a communication port configured to receive, from the computing device, an indication of an input electrical quantity;
a comparator configured to determine a difference between the measured output electrical quantity and the indicated input electrical quantity; and
a controller configured to instruct the power output module to stop supplying the electric current to the computing device based on the difference satisfying a warning state.

2. The power adapter of claim 1, wherein the output electrical quantity comprises an output current and the input electrical quantity comprises an input current.

3. The power adapter of claim 1, wherein the output electrical quantity comprises an output power and the input electrical quantity comprises an input power.

4. The power adapter of claim 1, wherein the output electrical quantity comprises an output voltage and the input electrical quantity comprises an input voltage.

5. The power adapter of claim 1, wherein the communication port is further configured to send a warning message to the computing device based on the difference satisfying the warning state.

6. The power adapter of claim 1, wherein the difference satisfying the warning state includes the difference meeting a threshold.

7. The power adapter of claim 1, wherein the difference satisfying the warning state includes the difference exceeding a threshold.

8. The power adapter of claim 7, wherein the controller is configured to change the threshold in response to receiving a firmware update.

9. The power adapter of claim 1, wherein the power adapter comprises a Universal Serial Bus (USB) power supply.

10. A power adapter comprising:
a power output module configured to supply electric current to a computing device;
an electrical monitor configured to measure an output electrical quantity of the power output module;
a communication port configured to:
send, to the computing device, an indication of the measured output electrical quantity; and
receive, from the computing device, an instruction to stop supplying the electric current; and
a controller configured to, in response to the communication port receiving the instruction to stop supplying the electric current, instruct the power output module to stop supplying the electric current to the computing device.

11. The power adapter of claim 10, wherein the output electrical quantity comprises at least one of voltage, current, and power.

12. A computing device comprising:
a display;
a rechargeable battery configured to provide power to the display;
a power input module configured to absorb electric current from a power adapter and supply electric current to the rechargeable battery;
an electrical monitor configured to measure an input electrical quantity of the power input module;
a communication port configured to receive, from the power adapter, an indication of an output electrical quantity;
a comparator configured to determine a difference between the measured input electrical quantity and the indicated output electrical quantity; and
a controller configured to instruct the power adapter to stop supplying the electric current to the computing device based on the difference satisfying a warning state.

13. The computing device of claim 12, wherein the controller is further configured to instruct the display to present a warning based on the difference satisfying the warning state.

14. The computing device of claim 12, wherein the controller is further configured to shut the computing device down based on the difference satisfying the warning state.

15. The computing device of claim 12, wherein the difference satisfying the warning state includes the difference meeting a threshold.

16. The computing device of claim 12, wherein the difference satisfying the warning state includes the difference exceeding a threshold.

17. The computing device of claim 16, wherein the controller is further configured to change the threshold based on the computing device receiving an operating system update.

18. A computing device comprising:
a display;
a rechargeable battery configured to provide power to the display;
a power input module configured to absorb electric current from a power adapter and supply electric current to the rechargeable battery;
an electrical monitor configured to measure an input electrical quantity of the power input module; and
a communication port configured to send, to the power adapter, an indication of the measured input electrical quantity.

19. The computing device of claim 18, wherein:
the communication port is further configured to receive, from the power adapter, a warning message; and
the computing device further comprises a controller configured to instruct the display to present a warning statement in response to the communication port receiving the warning message.

20. The computing device of claim 18, wherein:
the communication port is further configured to receive, from the power adapter, a warning message; and
the computing device is configured to shut down in response to the communication port receiving the warning message.
